(19) United States
(12) Patent Application Publication
(10) Pub. No.: US 2024/0368764 A1
(43) Pub. Date: Nov. 7, 2024

(54) PROCESSING CHAMBER WITH GAS RECYCLING

(71) Applicant: Applied Materials,Inc., Santa Clara, CA (US)

(72) Inventors: Michael Robert Rice, Pleasanton, CA (US); Hanish Kumar Panavalappil Kumarankutty, Bengaluru (IN); Anand Joy, Bangalore (IN); Abhishek Basavaraju, Bengaluru (IN); Valibhav Gaikwad, Bengaluru (IN)

(73) Assignee: Applied Materials,Inc., Santa Clara, CA (US)

(21) Appl. No.: 18/383,671

(22) Filed: Oct. 25, 2023

(30) Foreign Application Priority Data
May 4, 2023 (IN) 202341031781

(51) Int. Cl. C23C 16/455; C23C 16/44; C23C 16/458

(52) U.S. Cl. CPC C23C 16/45593; C23C 16/4412; C23C 16/4586; C23C 16/45544

(57) ABSTRACT

Semiconductor manufacturing processing chambers with recycling capability and methods of recycling a chemical precursor are described. The processing chamber comprises a chamber body with a substrate support. The substrate support is spaced form the chamber lid to create a process region. A gas inlet provides a flow of gas to the process region and a recirculation plenum is in fluid communication with the process region. At least one fast-acting valve is connected to the recirculation plenum with a recirculation inlet line. A recirculation housing is in fluid communication with the recirculation inlet line and a recirculation outlet line. A recirculation piston valve allows a gas within the process chamber to be recycled into the original precursor container or into a different container for reuse.

### CROSS-REFERENCE TO RELATED APPLICATIONS

This application claims priority to India patent application No. 202341031781, filed May 4, 2023, the entire disclosure of which is hereby incorporated by reference herein.

### TECHNICAL FIELD

Embodiments of the disclosure generally relate to apparatus and methods for recycling precursors from processing chambers. In particular, embodiments of the disclosure relate to apparatus and methods for directing a flow of unreacted metal precursor to a recycling system and then to the ampoule.

### BACKGROUND

Reliably producing submicron and smaller features is one of the key requirements of very large scale integration (VLSI) and ultra large scale integration (ULSI) of semiconductor devices. However, with the continued miniaturization of circuit technology, the dimensions of the size and pitch of circuit features, such as interconnects, have placed additional demands on processing capabilities. The various semiconductor components (e.g., interconnects, vias, capacitors, transistors) require precise placement of high aspect ratio features. Reliable formation of these components is critical to further increases in device and density.

Additionally, the electronic device industry and the semiconductor industry continue to strive for larger production yields while increasing the uniformity of layers deposited on substrates having increasingly larger surface areas. These same factors in combination with new materials also provide higher integration of circuits per unit area on the substrate.

During semiconductor manufacturing, expensive and potentially hazardous precursors and reactants are used. For example, chemical vapor deposition (CVD) atomic layer deposition (ALD) and etch processes often employ expensive chemical precursors which are used in excess to ensure complete reactions. These excess reactants and exhaust gases are sent to a scrubber for abatement and disposal. As a consequence, expensive chemicals are lost and potential greenhouse gases are released into the atmosphere. Currently, there are no such chemical recovery systems in use in the semiconductor industry.

Some molybdenum deposition processes use molybdenum chloride or molybdenum oxychloride as a metal precursor. Molybdenum chloride and oxychloride are very expensive precursors and only about 2% of the chemistry ends up on the wafer, resulting in about a 98% waste. Additionally, existing molybdenum chloride and oxychloride gas delivery systems are very complex and expensive. Frequently, multiple ampoules to store the molybdenum precursor are required. These are sub-fab mounted which requires the entire gas connection to the tool to be temperature controlled. This is difficult to accomplish and often suffers from reliability issues.

Accordingly, there is a need in the art for apparatus and methods to recycle semiconductor manufacturing process gases and reduce the environmental impact of semiconductor manufacturing.

### SUMMARY

One or more embodiments of the disclosure are directed to semiconductor manufacturing processing chambers including a chamber body having a sidewall, bottom and lid enclosing an interior. A substrate support is within the interior of the chamber body. The substrate support has a support surface spaced a distance from the chamber lid to create a process region. A gas inlet is configured to provide a flow of gas to the process region. An exhaust plenum is in fluid communication with the process region. At least one exhaust piston valve is connecting the exhaust plenum with an exhaust line and a recirculation inlet line. The at least one piston valve is configured to provide fluid communication between one of the exhaust line or the recirculation inlet line. A recirculation housing is in fluid communication with the recirculation inlet line.

Additional embodiments of the disclosure are directed to semiconductor manufacturing processing chambers including a chamber body having a sidewall, bottom and lid enclosing an interior. A substrate support is within the interior of the chamber body. The substrate support has a support surface spaced a distance from the chamber lid to create a process region. A gas inlet is configured to provide a flow of gas to the process region. The gas inlet includes a backer plate spaced a distance from a showerhead to form an inlet plenum. The inlet plenum is in fluid communication with the process region through the showerhead. An exhaust plenum is in fluid communication with the process region. A recirculation housing is on the lid of the processing chamber. The recirculation housing is a piston pump having a recirculation plenum bounded by a movable wall, a bellows and fixed wall. The recirculation plenum is in fluid communication with a recirculation inlet line and a recirculation outlet line. At least one exhaust piston valve connects the exhaust plenum with an exhaust line and the recirculation inlet line. At least one piston valve is configured to provide fluid communication between one of the exhaust line or the recirculation inlet line. An ampoule connection is in fluid communication with the recirculation plenum through the recirculation outlet line and a recirculation piston valve.

Further embodiments of the disclosure are directed to methods of recycling a semiconductor manufacturing metal precursor. The methods include directing a gas from a process region of a processing chamber from a recirculation plenum through at least one fast-acting valve and a recirculation inlet line, and directing the gas from the recirculation plenum to an ampoule through a recirculation outlet line and a recirculation valve.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 shows a semiconductor manufacturing processing chamber with a recirculation pump in the expanded position in accordance with one or more embodiments of the disclosure.

FIG. 2 shows the semiconductor manufacturing processing chamber of FIG. 1 in which the recirculation pump is in the compressed position in accordance with one or more embodiments of the disclosure.

FIG. 3 shows a schematic representation of the semiconductor manufacturing processing chamber and flow paths/valves.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

“Atomic layer deposition” or “cyclical deposition” as used herein refers to a process comprising the sequential exposure of two or more reactive compounds to deposit a layer of material on a substrate surface. The substrate, or portion of the substrate, is exposed separately to the two or more reactive compounds which are introduced into a reaction zone of a processing chamber. In a time-domain ALD process, exposure to each reactive compound is separated by a time delay to allow each compound to adhere and/or react on the substrate surface and then be purged from the processing chamber. These reactive compounds are said to be exposed to the substrate sequentially. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay, a purge gas, such as argon, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

In an embodiment of a spatial ALD process, a first reactive gas and second reactive gas (e.g., nitrogen gas) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas. The gas curtain can be any suitable gas separation arrangement known to the skilled artisan. For example, in some embodiments of the a spatial ALD process chamber, a gas curtain is formed by a combination of purge gas ports and vacuum ports to maintain separation between the reactive gases to prevent gas-phase reactions.

As used in this specification and the appended claims, the terms “reactive compound”, “reactive gas”, “reactive species”, “precursor”, “process gas” and the like are used interchangeably to mean a substance with a species capable of reacting with the substrate surface or material on the substrate surface in a surface reaction (e.g., chemisorption, oxidation, reduction, cycloaddition). The substrate, or portion of the substrate, is exposed sequentially to the two or more reactive compounds which are introduced into a reaction zone of a processing chamber.

One or more embodiments of the disclosure advantageously provide apparatus for reducing the high cost of an atomic layer deposition (ALD) chemistry by over 75%. In some embodiments, chemistry is captured, recompressed and returned to the gas supply ampoule for use on the next ALD cycle. Some embodiments advantageously keep the chemistry in the gas phase throughout the recycling process.

Current chemistry delivery solutions deliver the molybdenum chloride or molybdenum oxychloride from the sub-fab to the tool(s). Gas line lengths are often 75 to 100 feet long. The sub-fab system is very large (about 4 m³) and the gas needs to be maintained above about 150° C. throughout transmission to the point of use. Accordingly, some embodiments of the disclosure advantageously provide apparatus and methods that reduce chemistry consumption by greater than or equal to 75% allowing the gas supply to be located at the chamber because much less chemistry is consumed.

As used herein, the chemical formulae MoClₓ and MoOₓCl_{y} refer to “molybdenum chloride” and “molybdenum oxychloride”, respectively. The skilled artisan will recognize that the generic formulae used for molybdenum chloride and oxychloride are not indicative of any particular stoichiometric relationship. The formulae MoClₓ and MoOₓCl_{y} provide identification of the elements present in the particular precursor compound, not the ratio of the elements. For example, molybdenum (III) chloride and molybdenum (V) chloride are both referred to herein as MoClₓ, or molybdenum chloride, unless a particular oxidation state or stoichiometric are specified.

Current approaches to the atomic layer deposition of molybdenum leave approximately 2% of the chemistry on the wafer, wasting about 98% of the MoClₓ or MoOₓCl_{y} precursor to go down to the pump line or deposits throughout the chamber, foreline, pump, etc. While the various embodiments of the disclosure refer to the use of molybdenum chloride or oxychloride precursors, the skilled artisan will recognize that the disclosure is not limited to molybdenum precursors, chloride precursors or oxychloride precursors, and that any suitable precursor can be used.

Some embodiments of the disclosure flow the precursor (e.g., MoClₓ or MoOₓCl_{y}) from the source ampoule to the chamber and then pull the reactive gas into a piston pump, followed by pushing the gas back into the ampoule. The gas remains at low pressure (e.g., between 2 torr and 50 torr) with all the internal surfaces heated above the dew point (e.g., between 100° C. and 200° C.). Heating and reduced pressure keep the gas in the gas phase, rather than a liquid or going back to a solid which the gas might be at atmospheric pressure and temperature).

Some embodiments of the disclosure add a heated local pump and gas transmission line and valves to the gas flow path of the processing chamber. In some embodiments, spatial separation of ALD gases along with station sealing allow for the consistent recovery of unreacted precursor.

The piston pump of some embodiments is constructed out of a typical semiconductor processing material like stainless steel with bellows to be able to operate at elevated temperatures without particulate generation. The piston pump of some embodiments is driven by a servo-ball screw actuator for precise speed and displacement control. The piston pump of some embodiments is four times larger in volume than the process chamber, so that 4 of 5 (80%) of the gas volume will be recycled.

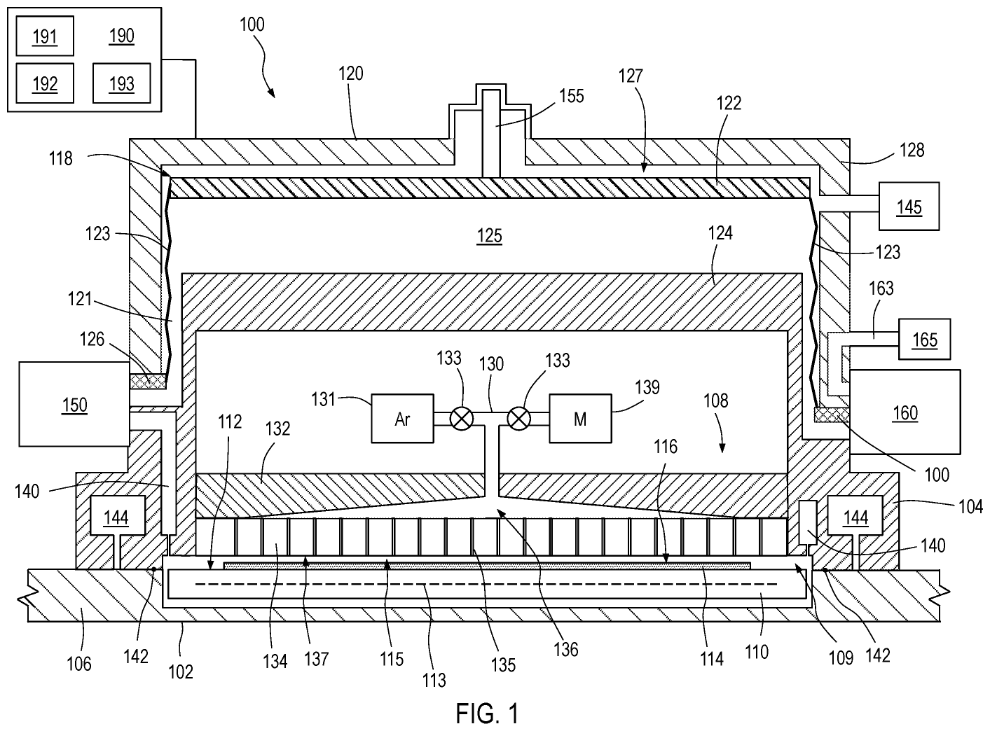

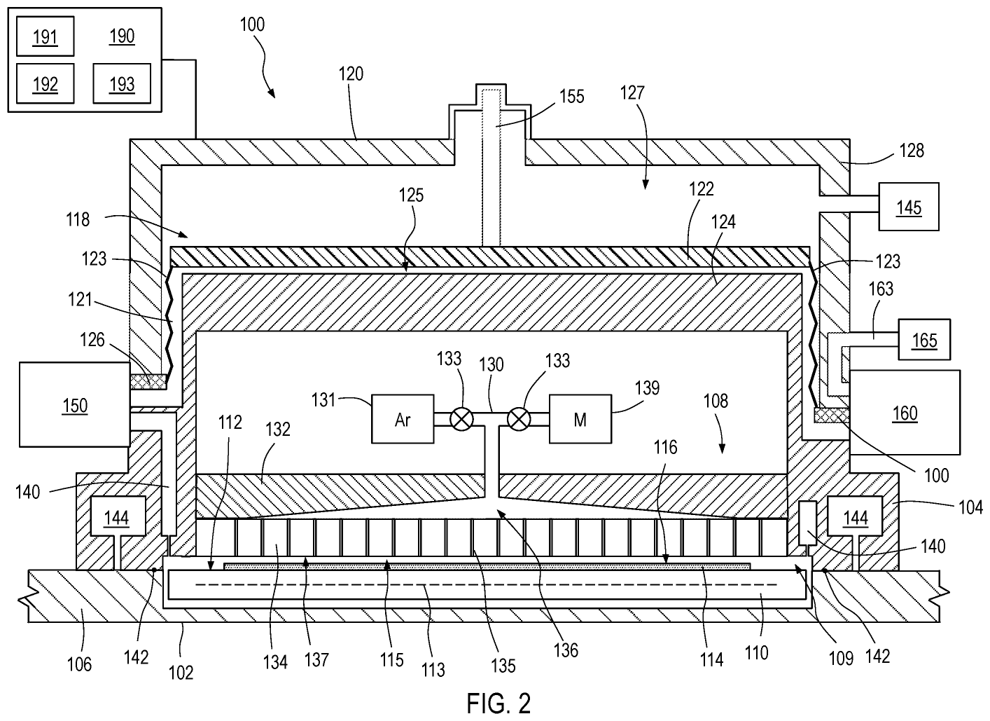

FIG. 1 shows a semiconductor manufacturing processing chamber 100 with a recirculation pump 118 in the expanded position in accordance with one or more embodiments of the disclosure. FIG. 2 shows the semiconductor manufacturing processing chamber 100 of FIG. 1 in which the recirculation pump 118 is in the compressed position in accordance with one or more embodiments of the disclosure.

The semiconductor manufacturing processing chamber 100 includes a chamber body 102 with a sidewall 104, bottom 106 and chamber lid 108 that enclose an interior 109 of the chamber. The chamber body 102 can be made of any suitable material known to the skilled artisan. For example, the chamber body 102 in some embodiments is made of aluminum. The various components of the embodiments illustrated in the Figures have different cross-hatching for visualization purposes. The different cross-hatching is only to make it easier to distinguish between parts and is not related to the materials of construction.

A substrate support 110 is positioned within the interior 109 of the chamber body 102. The substrate support 110 has a support surface 112 configured to support a semiconductor wafer 114. The support surface 112 is spaced a distance from the chamber lid 108 to create a process region 115. The top surface 116 of the semiconductor wafer 114 faces the chamber lid 108 so that the top surface 116 is exposed to process gases.

In some embodiments, the substrate support 110 comprises a heater 113. The heater 113 can be made of any suitable material known to the skilled artisan. In some embodiments, heater 113 comprises an electrode embedded within the substrate support 110. In some embodiments, a power supply (not shown) is connected to the electrode and power applied to the electrode causes resistive heating in the heater 113 and elevates the temperature of the substrate support 110 and semiconductor wafer 114.

In some embodiments, the substrate support 110 further comprises an electrostatic chuck (ESC) (not shown). In embodiments with an ESC, at least one power supply is connected to at least one electrode within the ESC and configured to polarize the electrodes of the ESC to generate an electrostatic charge that can chuck the semiconductor wafer 114 during processing. The skilled artisan will be familiar with the design and construction of an electrostatic chuck.

A gas inlet 130 is configured to provide a flow of gas to the process region 115. The chamber lid 108 of the illustrated embodiments comprises a backer plate 132 and a showerhead 134. The backer plate 132 and showerhead 134 are spaced a distance to form an inlet plenum 136. In the illustrated embodiments, the back plate 132 has a concave shaped front surface which forms a funnel shaped inlet plenum 136. The showerhead 134 includes a plurality of apertures 135 that allow a process gas to flow from the inlet plenum 136 to the process region 115. In some embodiments, the front surface 137 of the showerhead 134 is spaced a distance from the top surface 116 of the semiconductor wafer 114 during processing so that the process region 115 is between the top surface 116 of the semiconductor wafer 114 and the front surface 137 of the showerhead 134. The backer plate 132 and showerhead 134 are part of the gas inlet 130 in the illustrated embodiment because a gas flowing through gas inlet 130 passes through the inlet plenum 136 and showerhead 134 into the process region 115. In some embodiments, the gas inlet 130 is as close to the backer plate 132 as possible to minimize any dead volume in the system to increase the amount of precursor that can be recovered.

In some embodiments, the gas inlet 130 comprises one or more gas source. For example, an inert gas source 131 and a metal precursor source 139 are shown connected to gas inlet 130. In some embodiments, one or more valves 133 are located between the inert gas source 131 and/or metal precursor source 139 to control the flow of gases into the gas inlet 130.

A recirculation plenum 140 is in fluid communication with the process region 115 and recirculation volume 125. In use, process gases from the process region 115 flow into the recirculation plenum 140 when the recirculation pump 118 executes the suction stroke. However, to prevent unintended leakage of expensive and/or dangerous chemicals, the sidewall 104 or chamber lid 108 (depending on the configuration of the semiconductor manufacturing processing chamber 100) has an O-ring 142. An exhaust plenum 144 is arranged concentrically around the process region 115. Gaseous species exiting the process region 115 are prevented from passing to the outside of the semiconductor manufacturing processing chamber 100 by O-ring 142. If a species were to pass through the O-ring 142, the exhaust plenum 144 acts as a backup to prevent leakage into the environment.

At least one fast-acting valve 150 is connected to the recirculation plenum 140. While the term “fast-acting valve” is used to describe the different valves, the skilled artisan will understand that other types of valves can be used and fall within the definition of a fast-acting valve. For example, suitable fast-acting valves include, but are not limited to ALD valves and isolation valves. The fast-acting valves can be pneumatically actuated, electrically actuated or manually actuated. The fast-acting valves 150 are connected to the recirculation plenum 140. (145 and 150 are same parts) (160 and 145 are same parts). All the fast-acting valves 150 of some embodiments can be configured to provide fluid communication between the recirculation plenum 140 and one or more of recirculation path through the fast-acting valve 150 or recirculation inlet line 121. In some embodiments, the at least one fast-acting valve 150 is configured to isolate the recirculation plenum 140 from the recirculation inlet line 121. In some embodiments, the fast-acting valve 150 is configured to provide fluid communication between the recirculation plenum 140 and recirculation inlet line 121.

In some embodiments, there is one fast-acting valve 150 connecting the recirculation plenum 140 with the recirculation volume 125 through the recirculation inlet line 121. In some embodiments, there is more than one at least one fast-acting valve 150 connecting the recirculation plenum 140 with the recirculation volume 125 through the recirculation inlet line 121. In some embodiments, there are two, three or four at least one fast-acting valve 150 connecting the recirculation plenum 140 with the recirculation volume 125 through the recirculation inlet line 121. In some embodiments, when there is more than one at least one fast-acting valve 150, the at least one fast-acting valves 150 are positioned equidistant around the process region 115. For example, if there are two at least one fast-acting valve 150 then each is positioned 180° from the center of the process region 115. In an embodiment in which there are three at least one fast-acting valve 150, are positioned at 120° intervals around the center of the process region 115. In some embodiments, there are four, at least one fast-acting valve 150 and each is positioned equidistant from the other at least one so that each is located at 90° intervals around the center of the process region 115.

The recirculation pump 118 is inside the recirculation housing 120 of some embodiments acts as a piston pump 118 and has recirculation volume 125 bounded by a movable wall 122, a bellow 123 and a fixed wall 124. In some embodiments, the bellows 123 connects to a bellows flange 126 positioned atop the chamber lid 108 or sidewall 104 of the chamber body 102. The bellows 123 can be any suitable component known to the skilled artisan that allows for the movement of the movable wall 122 while maintaining a seal between the recirculation volume 125 and the outside volume 127 made by the recirculation housing 120 and the recirculation volume 125.

The recirculation housing 120 of some embodiments further comprises an upper wall 128 that bounds the movable wall 122 and bellow 123. Where the upper wall 128 is included, the outside volume 127 is located between the movable wall 122 and bellows 123 and the upper wall 128 so that the movable wall 122 is within the recirculation housing 120 volume. In some embodiments, the recirculation housing 120 further comprises a vacuum source 145 connected to the outside volume 127 of the recirculation housing 120 outside the recirculation volume 125.

The recirculation volume 125 is in fluid communication with the recirculation inlet line 121 and recirculation outlet line 129. The recirculation outlet line 129 forms a fluid connection between the recirculation volume 125 and the recirculation valve 160 While the term “recirculation valve” is used to describe the different valves, the skilled artisan will understand that other types of valves can be used and fall within the definition of a recirculation valve. For example, suitable recirculation valves include, but are not limited to ALD valves and isolation valves. The recirculation valves can be pneumatically actuated, electrically actuated or manually actuated.

In some embodiments, the recirculation volume 125 is in fluid communication with a precursor ampoule 165 through a recirculation valve 160 and recirculation exhaust line 163 which is in fluid communication with the recirculation outlet line. The precursor ampoule 165 of some embodiments is the same container as the metal precursor source 139 that is connected to the gas inlet 130, as discussed earlier, or can be a different container. For example, in some embodiments, the recirculation volume 125 is configured to refill the metal precursor source 139 with unreacted metal precursor between individual exposures to the metal precursor as part of the ALD processing. In some embodiments, the recirculation volume 125 is configured to fill a secondary precursor storage container (precursor ampoule 165) which is different than the metal precursor source 139 connected to the gas inlet 130. In embodiments using a secondary precursor storage container (precursor ampoule 165), the chemistry filling the precursor ampoule 165 can be subjected to post-fill processing (e.g., purification) or can be used in a subsequent process as a replacement for the metal precursor source 139 connected to the gas inlet 130.

The recirculation housing 120 of some embodiments further comprises an actuator 155. The actuator is configured to move the movable wall 122 to change the volume of the recirculation volume 125. The volume of the recirculation volume 125 of some embodiments is changeable between an expanded volume (as shown in FIG. 1) and a compressed volume (as shown in FIG. 2). Movement of the movable wall 122 causes changes in the bellows 123 between a compressed state and an expanded state. When the movable wall 122 is in the expanded volume position, the bellows 123 is in the expanded state. When the movable wall 122 is in the compressed volume position, the bellows 123 is in the compressed state. Stated differently, the piston pump of some embodiments further comprises an actuator 155 that is configured to move the movable wall 122 to change the volume of the recirculation volume 125 between an expanded volume and a compressed volume, and compress or expand the bellows 123.

The expanded volume of the recirculation pump 118 can be any suitable volume, depending on the size of the process region 115 and other factors. In some embodiments, the expanded volume of the recirculation pump 118 is greater than or equal to 3 L, 3.5 L, 4 L, 4.5 L, 5 L, 5.5 L, 6 L, 6.5 L or 7 L. In some embodiments, the expanded volume of the recirculation pump 118 is a factor of the volume of the process region 115. In some embodiments, the expanded volume of the recirculation pump 118 is greater than or equal to 1 time, 2 times, 3 times, 4 times, 5 times, 6 times, 7 times, 8 times or 9 times the volume of the process region 115. In an exemplary embodiment, the recirculation volume 125 of the recirculation pump 118 is about four times the volume of the process region 115 so that upon filling of the process region 115 and recirculation volume 125 with the metal precursor, 80% (⅘ths) of the total volume of metal precursor exists in the recirculation volume 125 and can be recovered for recycling.

The compressed volume is less than the expanded volume. In some embodiments, the compressed volume is less than or equal to 1 L, 0.9 L, 0.8 L, 0.7 L, 0.6 L, 0.5 L, 0.4 L, 0.3 L, 0.2 L, 0.1 L, 0.09 L, 0.08 L, 0.07 L, 0.06 L or 0.05 L. The compression ratio of recirculation housing 120 in some embodiments is greater than or equal to 50×, 60×, 70×, 80×, 85×, 90×, 95×, 96×, 97×, 98× or 99× the expanded displacement. For example, a recirculation volume 125 with an expanded volume of 6.5 L, which is compressed to a volume of about 0.3 L has a compression ratio of about

The actuator 155 can be any suitable component known to the skilled artisan that is compatible with the hardware requirements. For example, the actuator 155 of some embodiments has a sufficient force and/or stroke length and/or speed to move the movable wall 122 between the compressed and expanded positions. In some embodiments, the stroke of the actuator 155 is greater than or equal to 2 cm, 3 cm, 4 cm, 5 cm or 6 cm. In some embodiments, the actuator 155 is a linear actuator. In some embodiments, the linear actuator comprises one or more of a mechanical actuator, a hydraulic actuator, a pneumatic actuator, a piezoelectric actuator, a coiled actuator, a telescoping actuator and motors like servo motors or stepper motors or any modes of actuation. In some embodiments, the linear actuator comprises one or more of a ball screw drive or linear screw or a belt drive actuator.

In some embodiments, the fixed wall 124 of the recirculation housing 120 is temperature controlled to prevent condensation of the metal or any form of precursor within the recirculation volume 125. In some embodiments, the fixed wall 124 of the recirculation housing 120 is connected to, or part of, the chamber lid 108 or backer plate 132 or showerhead 134. In some embodiments, the fixed wall 124 is positioned in close proximity to a temperature-controlled gas inlet 130 (e.g., temperature-controlled showerhead 134 and/or backer plate 132) so that the fixed wall 124, and subsequently the recirculation volume 125 are heated by the proximity. In some embodiments, one or more of the fixed wall 124 or upper wall 128 of the recirculation housing 120 are equipped with a heater (e.g., a resistive heater) to control the temperature of the recirculation pump 118 and recirculation line comprises of recirculation inlet line 121 recirculation outlet line 129 (not marked in diagram). and recirculation exhaust line 163 independently of the adjacent components.

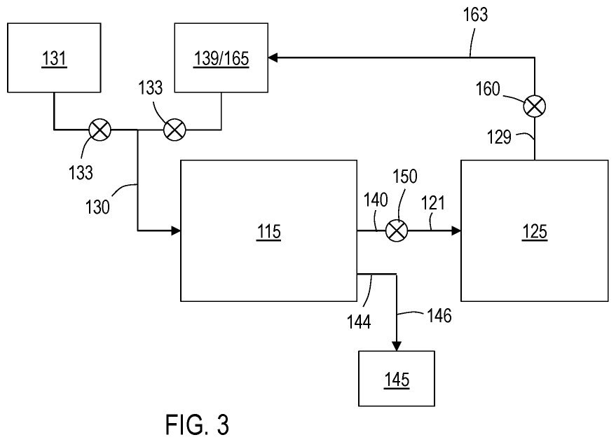

Referring to FIGS. 1 through 3, one or more embodiments of the disclosure are directed to methods of recycling a semiconductor manufacturing precursor. FIG. 3 shows a schematic representation of the semiconductor manufacturing processing chamber 100 and flow paths/valves.

The method of some embodiments comprises directing a gas from a process region 115 of a semiconductor manufacturing processing chamber 100 to an exhaust plenum 144. The exhaust plenum 144 of some embodiments surrounds the process region 115 in a circular shape so that the exhaust plenum 144 is concentric to the substrate support 110. In some embodiments, the exhaust plenum 144 surrounds the recirculation plenum 140.

The foreline (not shown) is in fluid communication with the exhaust plenum 144. The vacuum seal (e.g., O-ring 142) blocks the flow of gas from leaving the process region 115 to the exhaust plenum 144, to allow the flow of gas to pass through at least one fast-acting valve 150 to the recirculation inlet line 121.

To fill the recirculation volume 125 of the recirculation pump 118, the at least one fast-acting valve 150 is adjusted to allow the gas to pass through the at least one fast-acting valve 150 to the recirculation inlet line 121 and into the recirculation volume 125. Additionally, the recirculation valve 160 is closed to prevent gas from flowing out of the recirculation volume 125 through the recirculation outlet line 129. The recirculation valve 160 can be closed before, at the same time as, or after opening the at least one fast-acting valve 150 to allow flow from the process region 115 to the recirculation volume 125.

In some embodiments, the one or more valves 133 on the gas inlet 130 are closed prior to adjusting the at least one fast-acting valve 150 to send the gas to the recirculation volume 125. In some embodiments, the one or more valves 133 on the gas inlet 130 are closed at the same time as adjusting the at least one exhaust piston valve 150 to send the gas to the recirculation volume 125. In some embodiments, the one or more valves 133 on the gas inlet 130 are closed after adjusting the at least one exhaust piston valve 150 to send the gas to the recirculation volume 125.

With the at least one fast-acting valve 150 adjust to allow fluid communication between the process region 115 and the recirculation volume 125, the total volume of the process gas is the sum of the process region 115, the recirculation volume 125 and the intervening gas flow paths (e.g., recirculation plenum 140, at least one fast-acting valve 150, and recirculation inlet line 121). Typically, the volume of the intervening gas flow paths are relatively small compared to the volume of the process region 115 and recirculation volume 125 and contribute negligibly to the overall volume. For example, where the recirculation volume 125 is four times larger than the process region 115, the amount of gas present in the recirculation volume 125 upon reaching equilibrium is estimated as 80% of the total gas volume in the closed system. In some embodiments, the volume of the process region 115 includes the volume of gas present in the recirculation plenum 140. In some embodiments, the volume of the gas in the recirculation volume 125 includes the volume of gas in the recirculation inlet line 121 and recirculation housing recirculation outlet line recirculation outlet line 129.

In some embodiments, filling the recirculation volume 125 further comprises changing the recirculation volume 125 when the at least one fast-acting valve 150 is in the open position. In some embodiments, the movable wall 122 is at the compressed position, as shown in FIG. 2, when the at least one fast-acting valve 150 is opened to allow fluid communication between the process region 115 and the recirculation volume 125. Once the at least one fast-acting valve 150 is opened, the movable wall 122 can be moved using the actuator 155 to expand the recirculation volume 125 until the movable wall 122 is in the expanded position, as shown in FIG. 1, representing the maximum possible of the recirculation volume 125. Moving the movable wall 122 causes the volume within the closed system to expand so that gases in the process region 115 are effectively pulled into the recirculation volume 125 by the suction created because of movement of the movable wall 122.

Once the movable wall 122 has reached the expanded position and the gas has flowed into the recirculation volume 125, each of the fast-acting valve 150 is closed to isolate the combined volume in the recirculation inlet line 121, recirculation volume 125 and recirculation outlet line 129. Closing the at least one fast-acting valve 150 means that the fluid connection between the recirculation volume 125 and process region 115 is broken. In some embodiments, closing the at least one fast-acting valve 150 and breaking the seal 142 forms a fluid connection between the process region 115 and the exhaust plenum 144 so that the remaining reactive gas within the process region 115 can be removed from the process region 115 to allow for the next step in the process. In some embodiments, before, after or during closing of the at least one fast-acting valve 150 the one or more valves 133 of the gas inlet 130 can be adjusted to allow a flow of a purge gas (e.g., from inert gas source 131) into the process region 115 and to the vacuum plenum 144 by breaking the seal (e.g., O-ring 142).

Before, after or during the purging of the process region 115 with a purge gas (e.g., from inert gas source 131), the gas within the recirculation volume 125 can be recycled into a new container (e.g., precursor ampoule 165) or into the existing metal precursor source 139. To recycle the gas in the process region 115, the recirculation valve 160 is moved to the open position to create a fluid connection between the recirculation volume 125 and the metal precursor source 139 (or precursor ampoule 165) through the recirculation outlet line 129. Stated differently, in some embodiments, the gas is directed from the recirculation volume 125 to the metal precursor source 139 (or precursor ampoule 165) through the recirculation outlet line 129 and recirculation valve 160.

In some embodiments, directing the gas from the recirculation volume 125 to the metal precursor source 139 (or precursor ampoule 165) further comprises moving the movable wall 122 to change the recirculation volume 125. For example, after opening the recirculation valve 160, the movable wall 122 in some embodiments is moved using actuator 155 from the expanded position (as shown in FIG. 1) to the compressed position (as shown in FIG. 2), expelling the gas from within the recirculation volume 125 into the metal precursor source 139 (or precursor ampoule 165). Once the gas in the recirculation volume 125 has been expelled to metal precursor source 139 (or precursor ampoule 165), the recirculation valve 160 is adjusted to isolate the recirculation volume 125 from the recirculation exhaust line 163.

In some embodiments, the recirculation volume 125 is flushed with an inert gas to allow for cleaning of the recirculation volume 125 for future use. To clean the recirculation volume 125, the recirculation valve 160 is adjusted to allow fluid communication through the recirculation valve 160 to exhaust line 163 and connecting to a vacuum source (not shown) instead of connection to the precursor can. The at least one fast-acting valve 150 is adjusted to allow fluid communication between the process region 115 and the recirculation volume 125 through the at least one fast-acting valve 150 and recirculation inlet line 121. An inert gas flow (i.e., from inert gas source 131 or other source) is provided through the gas inlet 130 through one or more valves 133. The gas flows from the inert gas source 131 through one or more valves 133 and gas inlet 130 into inlet plenum 136. Gas then passes form the inlet plenum 136 through the plurality of apertures 135 of the showerhead 134 into the process region 115. The gas in the process region 115 can then flow through the at least one fast-acting valve 150, the recirculation inlet line 121, the recirculation volume 125, the recirculation outlet line 129, the recirculation piston valve 160, the exhaust line 162 to the vacuum source 145, flushing the flow path and the recirculation volume 125. In some embodiments, cleaning the recirculation volume 125 further comprises moving the movable wall 122 between the expanded position and the compressed position one or more times to create a pulsing effect on the gas flow.

In some embodiments, the method further comprises heating the recirculation volume 125 to prevent condensation of the precursor. Heating the recirculation volume 125 can be accomplished by any suitable technique known to the skilled artisan. In some embodiments, heating the recirculation volume 125 is done by positioning the fixed wall 124 adjacent a heated region of the semiconductor manufacturing processing chamber 100, for example, a heated showerhead 134. In some embodiments, heating the recirculation volume 125 comprises powering a heating element within one or more of the fixed wall 124 or movable wall 122 of the recirculation housing 120. In some embodiments, heating the recirculation volume 125 comprises powering a heating element within one or more of the sidewall 104 or backer plate 132 of the process chamber 100.

In some embodiments, as shown in FIGS. 1 and 2, a controller 190 is coupled to one or more of the semiconductor manufacturing processing chamber 100, the at least one fast-acting valve 150, the recirculation valve 160, one or more valves 133 of the gas inlet 130, the heater 113 of the substrate support 110, the actuator 155 of the recirculation housing 120 (or piston pump) or components thereof. For example, the system controller 190 may control the operation of the semiconductor manufacturing processing chamber 100, actuators, valves, flow controllers, power supplies, etc., and any monitoring components known to the skilled artisan that are included in the system. In operation, the system controller 190 may enable data collection and feedback from the semiconductor manufacturing processing chamber 100 to coordinate system performance.

The system controller 190 generally includes a central processing unit (CPU) 192, memory 194, and support circuits 196. The CPU 192 may be one of any form of a general-purpose processor that can be used in an industrial setting. The memory 194, or non-transitory computer-readable medium, is accessible by the CPU 192 and may be one or more of memory such as random-access memory (RAM), read only memory (ROM), floppy disk, hard disk, or any other form of digital storage, local or remote. The support circuits 196 are coupled to the CPU 192 and may comprise cache, clock circuits, input/output subsystems, power supplies, and the like. The various methods disclosed herein may generally be implemented under the control of the CPU 192 by the CPU 192 executing computer instruction code stored in the memory 194 (or in memory of a particular process chamber) as, for example, a software routine. When the computer instruction code is executed by the CPU 192, the CPU 192 controls the chambers or valves to perform processes in accordance with the various methods.

In some embodiments, the controller 190 has one or more predetermined configurations for controlling components of the semiconductor manufacturing processing chamber 100. In some embodiments, the controller 190 has

In some embodiments, the at least one controller 190 has a first configuration to fill the recirculation volume 125 with a precursor from the process region 115. The first configuration comprises instructions to move the movable wall 122 of the piston pump (recirculation housing 120) with the actuator 155 to the expanded volume, operating the recirculation piston valve 160 to isolate the recirculation outlet line 129, and operating the at least one piston valve 150 to direct a flow of gas from the exhaust plenum 140 to the recirculation volume 125 through the recirculation inlet line 121.

In some embodiments, the at least one controller 190 has a second configuration to empty the recirculation volume 125 into the ampoule 165 or metal precursor source 139. The second configuration comprises instructions to operate the at least one exhaust piston valve 150 to isolate the recirculation inlet line 121 with the recirculation volume 125, operate the recirculation piston valve 160 to provide fluid communication between the recirculation volume 125 and the ampoule 165 (or metal precursor source 139) through the recirculation outlet line 129, and move the movable wall 122 of the piston pump (recirculation housing 120) with the actuator 155 to expel gas within the recirculation volume 125 through the recirculation outlet line 129 to the ampoule 165 (or metal precursor source 139).

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A semiconductor manufacturing processing chamber comprising:
a chamber body having a sidewall, bottom and lid enclosing an interior;
a substrate support within the interior of the chamber body, the substrate support having a support surface spaced a distance from the chamber lid to create a process region;
a gas inlet configured to provide a flow of gas to the process region;
an exhaust plenum in fluid communication with the process region;
at least one exhaust piston valve connecting the exhaust plenum with an exhaust line and a recirculation inlet line, the at least one piston valve configured to provide fluid communication between one of the exhaust line or the recirculation inlet line; and
a recirculation housing in fluid communication with the recirculation inlet line.

2. The processing chamber of claim 1, wherein the gas inlet comprises a backer plate spaced a distance from a showerhead to form an inlet plenum.

3. The processing chamber of claim 2, wherein the recirculation housing is in fluid communication with a precursor ampoule through a recirculation valve in fluid communication with a recirculation outlet line.

4. The processing chamber of claim 3, wherein the recirculation housing is a piston pump having a recirculation volume bounded by a movable wall, a bellow and a fixed wall.

5. The processing chamber of claim 4, wherein the piston pump further comprises an actuator configured to move the movable wall to change a volume of the recirculation volume between an expanded volume and a compressed volume, and compress or expand the bellows.

6. The processing chamber of claim 5, wherein the expanded volume is greater than 5 L and the compressed volume is less than 0.5 L.

7. The processing chamber of claim 5, wherein the sidewall, backer plate, and fixed wall are temperature controlled to prevent condensation within the recirculation plenum.

8. The processing chamber of claim 5, wherein there are four fast-acting valves connecting the recirculation plenum with the recirculation volume through four or more recirculation inlet lines.

9. The processing chamber of claim 8, wherein the four or more recirculation plenums are positioned equidistant around the process region.

10. The processing chamber of claim 5, wherein the actuator comprises a ball screw drive.

11. The processing chamber of claim 5, wherein the substrate support comprises a heater.

12. The processing chamber of claim 5, wherein the recirculation housing comprises an upper wall and a sidewall connected to the lid of the chamber body enclosing a recirculation housing volume, the movable wall within the recirculation housing volume.

13. The processing chamber of claim 12, further comprising a vacuum connected between a vacuum source and the recirculation housing volume outside of the recirculation plenum.

14. The processing chamber of claim 5, further comprising at least one controller connected to the at least one exhaust piston valve, the recirculation piston valve and the actuator of the piston pump.

15. The processing chamber of claim 14, wherein the at least one controller has a first configuration to fill the recirculation plenum with a precursor from the process region, the first configuration comprising instructions to move the movable wall of the piston pump with the actuator to the expanded volume, operating the recirculation piston valve to isolate the recirculation outlet line, and operating the at least one piston valve to direct a flow of gas from the exhaust plenum to the recirculation plenum through the recirculation inlet line.

16. The processing chamber of claim 14, wherein the at least one controller has a second configuration to empty the recirculation plenum into the ampoule, the second configuration comprising instructions to operate the at least one exhaust piston valve to isolate the recirculation inlet line with the recirculation plenum, operate the recirculation piston valve to provide fluid communication between the recirculation plenum and the ampoule through the recirculation outlet line, and move the movable wall of the piston pump with the actuator to expel gas within the recirculation plenum through the recirculation outlet line to the ampoule.

17. A semiconductor manufacturing processing chamber comprising:
a chamber body having a sidewall, bottom and lid enclosing an interior;
a substrate support within the interior of the chamber body, the substrate support having a support surface spaced a distance from the chamber lid to create a process region;
a gas inlet configured to provide a flow of gas to the process region, the gas inlet comprising a backer plate spaced a distance from a showerhead to form an inlet plenum, the inlet plenum in fluid communication with the process region through the showerhead;
an exhaust plenum in fluid communication with the process region;
a recirculation housing on the lid of the processing chamber, the recirculation housing is a piston pump having a recirculation plenum bounded by a movable wall, a bellows and fixed wall, the recirculation plenum in fluid communication with a recirculation inlet line and a recirculation outlet line;
at least one exhaust piston valve connecting the exhaust plenum with an exhaust line and the recirculation inlet line, the at least one piston valve configured to provide fluid communication between one of the exhaust line or the recirculation inlet line; and
an ampoule connection in fluid communication with the recirculation plenum through the recirculation outlet line and a recirculation piston valve.

18. A method of recycling a semiconductor manufacturing metal precursor, the method comprising directing a gas from a process region of a processing chamber from an recirculation plenum at least one fast-acting valve and a recirculation inlet line; and
directing the gas from the recirculation plenum to an ampoule through a recirculation outlet line and a recirculation valve.

19. The method of claim 18, wherein the method further comprises heating the recirculation plenum to prevent condensation.

20. The method of claim 18, further comprising compressing or expanding a volume of the recirculation plenum by moving a movable wall bounding the recirculation plenum.
